(19) United States
(12) Patent Application Publication
(10) Pub. No.: US 2023/0156950 A1
(43) Pub. Date: May 18, 2023

(54) ADAPTABLE SECURING DEVICES FOR ELECTRONIC EQUIPMENT

(71) Applicant: ARRIS Enterprises LLC, Suwanee, GA (US)

(72) Inventors: Oswaldo Enrique LINARES RIVAS, Apodaca (MX); Carlos Paul GONZALEZ INDA, Guadalupe (MX); Luis Carlos LOPEZ MORENO, Apodaca (MX)

(73) Assignee: ARRIS Enterprises LLC, Suwanee, GA (US)

(21) Appl. No.: 17/987,734

(22) Filed: Nov. 15, 2022

Related U.S. Application Data
(60) Provisional application No. 63/280,249, filed on Nov. 17, 2021.

(51) Int. Cl. H05K 7/06

(52) U.S. Cl. CPC H05K 7/06

(57) ABSTRACT

Adaptable and/or adjustable securing devices are shown and disclosed. In one embodiment, the securing device includes a base and at least one elongate connector having opposed first and second longitudinal end portions. The first longitudinal end portion is pivotably connected to the base. The securing device additionally includes a coupler attached to, or formed with, the second longitudinal end portion, the coupler adapted to receive a fastener.

### CROSS REFERENCE TO RELATED APPLICATIONS

The present application claims the benefit of U.S. Provisional Patent Application Ser. No. 63/280,249 filed Nov. 17, 2021.

### BACKGROUND

The subject matter of this application relates to securing devices for electronic components on chassis of electronic equipment. Electronic equipment commonly use various electronic components and/or modules (e.g., power supply modules) that are installed into or onto the equipment chassis or framework to provide different functionalities. The electronic components/modules are manufactured by different vendors and thus the electronic components/modules generally have different dimensions and/or different fastening and/or securing devices. Therefore, the chassis needs to have fastening and/or securing devices that correspond with the dimensions and/or fastening and/or securing devices of the desired electronic components/modules.

However, having different chassis for each desired electronic component/module requires a lot of quality control, production logistics, and storage space. Additionally, when an electronic component/module of electronic equipment needs to be replaced in the field with an electronic component/module having different dimensions and/or fastening and/or securing devices, it can become difficult to mount the replacement electronic component/module to the equipment chassis.

What is desired, therefore, are securing devices that can adapt to fastening and/or securing devices of various electronic components/modules (such as various mounting positions).

### BRIEF DESCRIPTION OF THE DRAWINGS

For a better understanding of the invention, and to show how the same may be carried into effect, reference will now be made, by way of example, to the accompanying drawings, in which:

FIG. 1 is an isometric view of an example of a securing device attached to a chassis.

FIG. 2 is sectional view of the securing device of FIG. 1.

FIG. 3 is an exploded view of the securing device of FIG. 1.

FIG. 4 is a top view of an example of a chassis having four securing devices of FIG. 1 attached.

FIG. 5 is an isometric view of an example of a first electronic module attached to the chassis of FIG. 4 via securing devices of FIGS. 1-3.

FIG. 6 is an isometric view of an example of a second electronic module attached to the chassis of FIG. 4 via securing devices of FIGS. 1-3.

### DETAILED DESCRIPTION

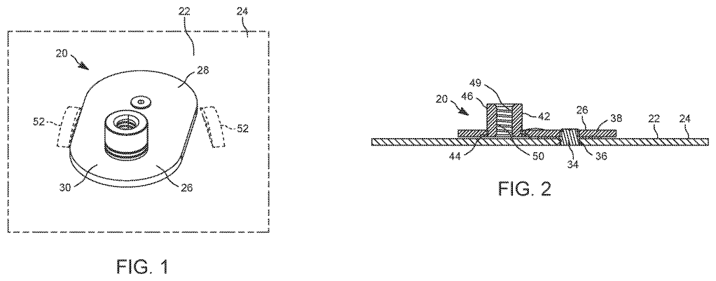

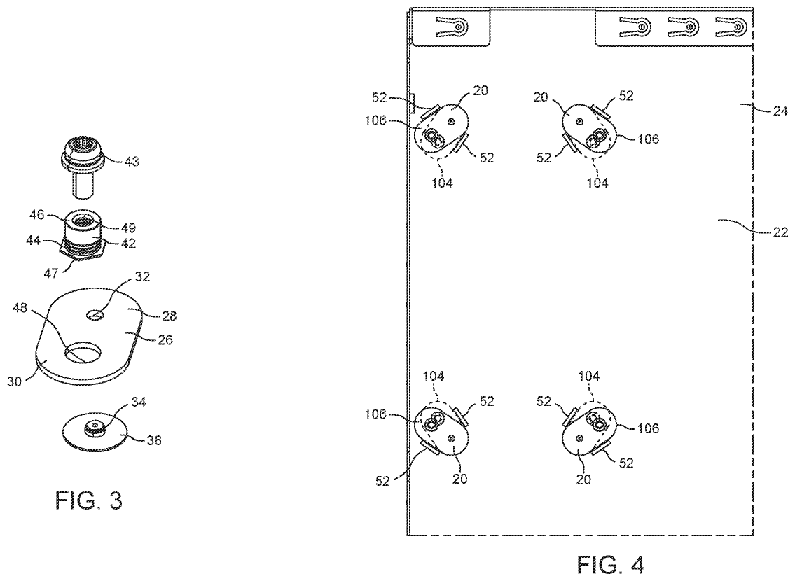

Referring to FIGS. 1-3, an example of a securing device 20 pivotably attached to a base 22 of chassis 24 is shown allowing the securing device to pivot or rotate relative to base 22. Securing device 20 includes a connector 26. In the example shown in FIGS. 1-3, connector 26 is elongate and planar. However, other embodiments of connector 26 may be non-elongate and/or nonplanar. In the example shown in FIGS. 1-3, elongate connector 26 is stadium-shaped but connector 26 may have other shape(s), such as square, rectangular, circular, etc.

Connector 26 includes opposed first and second end portions 28, 30. First end portion 28 is pivotably coupled or connected to base 22. In the example shown in FIGS. 1-3, first end portion 28 includes a first hole 32 that receives a pivot 34. Pivot 34 is attached to base 22, such as received in base hole 36. However, pivot 34 may alternatively be formed with base 22 in other examples. When connector 26 is elongate (such as shown in FIGS. 1-3), first and second end portions 28, 30 may also be referred to as first and second longitudinal end portions 28, 30.

In the examples shown in FIGS. 1-3, securing device 20 includes a washer 38 disposed between connector 26 and base 22 and/or in contact with connector 26 and base 22 to facilitate pivoting of connector 26 relative to base 22, such as by spacing connector 26 from base 22 (or creating a gap between connector 26 from base 22). In the example shown in FIGS. 1-3, washer 38 is attached to, or formed with, pivot 34. In other examples, washer 38 may be separate from pivot 34. In those examples, washer 38 includes a washer hole and pivot 34 is received in that washer hole. In other examples of securing device 20, the device may exclude washer 38. When securing device 20 does not include washer 38, pivot 34 may include a rib or ledge to support connector 26 spaced apart from base 22.

Securing device 20 includes a coupler 42 that receives a fastener, such as a fastener 43 to attach an electronic component to base 22 (e.g., screw, bolt, etc.). Coupler 42 includes opposed third and fourth end portions 44, 46. In the example shown in FIGS. 1-3, coupler 42 is elongate so the opposed third and fourth end portions may also be referred to as third and fourth longitudinal end portions 44, 46. Third end portion 44 is attached to, or formed with, second end portion 30 of connector 26. In the example shown in FIGS. 1-3, second end portion 30 includes a second hole 48 that receives coupler 42. Coupler 42 has any suitable shape(s). In the example shown in FIGS. 1-3, coupler 42 is cylindrical and elongate with a flange portion 47 that corresponds to the shape of second hole 48. In other examples, second hole 48 may include threads that correspond with threads of third end portion 44. Coupler 42 may include other suitable shape(s), such as spherical, cubical, triangular prism, hemispherical, cuboid, etc.

Fourth end portion 46 of coupler 42 includes an aperture 48 that receives a fastener, such as to fasten an electronic component to the fourth end portion. Aperture 48 may include one or more structures that correspond with structures of the fastener to fasten the fastener to the aperture, such as an aperture 50 having threads (or a threaded aperture) that correspond with the threads of the fastener. In the example shown in FIGS. 1-3, coupler 42 is a standoff that is received in second hole 48. However, other examples of coupler 42 may include structure(s) other than standoffs. In some embodiments, securing device 20 may exclude coupler 42. In some of those embodiments, second end portion 30 of connector 26 may include aperture 50.

In some examples, chassis 24 includes one or more stoppers 52 attached to, or formed with, base 22, as shown in FIG. 1. The stopper(s) are positioned on base 22 to limit pivoting of connector 26 to within any suitable ranges, such as 15, 20, 25, 30, 35, 40, and 45 degrees. Stopper(s) 52 may be any suitable shape(s). In the example shown in FIG. 1, stoppers 52 are bridge- or hat-shaped embossments of base 22. However, other examples of stoppers 52 include stoppers that are attached to, or formed with, base 22 without stamping or punching base 22 and/or that have different shape(s) and size(s).

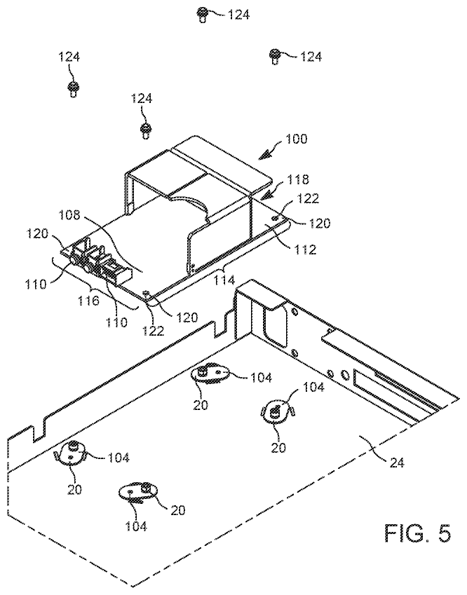

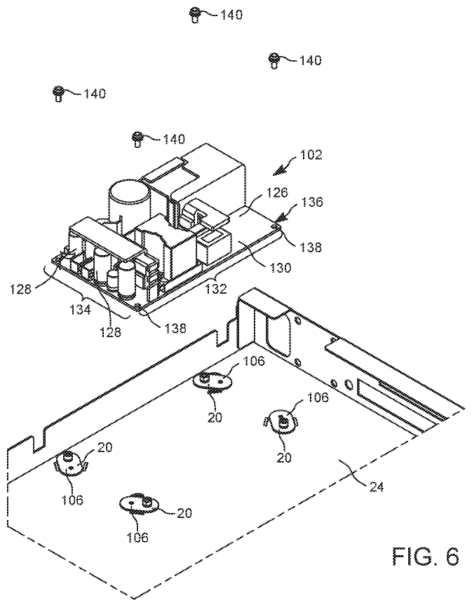

Referring to FIGS. 4-6, an example of chassis 24 having four securing devices 20 is shown. The securing devices are spaced from each other and positioned on base 22 of chassis 24 to allow attachment of a first electronic component/module 100 or a second electronic component/module 102 onto chassis 24. Base 22 includes stoppers 52 positioned on either side of each of the connectors 26 of securing devices 20 to limit pivoting of those connectors between a proximal position 104 and a distal position 106.

Electronic module 100 includes a frame 108 having various electronic components 110 attached to frame 108. Frame 108 has a perimeter portion 112 and has a first length 114 and a first width 116. First length 114 and first width 116 comprise a first area or first footprint 118. Perimeter portion 112 includes corners 120 having apertures 122 that receive fasteners 124. Fasteners 124 are received in couplers 42 of securing devices 20 when those securing devices are in proximal position 104.

Similarly, electronic module 102 includes a frame 126 having various electronic components 128 attached to frame 126. Frame 126 has a perimeter portion 130 and has a second length 132 and a second width 134. Second length 132 and second width 134 comprise a second area or second footprint 136. Perimeter portion 130 includes apertures 138 that receive fasteners 140. Fasteners 140 are received in couplers 42 of securing devices 20 when those securing devices are in distal position 106. Second length 132 and/or second width 134 of electronic module 102 is larger than first length 114 and/or first width 116. In other words, second footprint 136 is larger than first footprint 118.

Although FIGS. 4-6 show four securing devices 20, other examples of chassis 24 may include two, three, five, six, or more securing devices. Additionally, although chassis 24 in FIGS. 4-6 accommodates two different sized electronic modules, the chassis may accommodate additional different sized electronic modules, such as one or more electronic modules having a footprint that is larger than first footprint 118 but smaller than second footprint 136.

The securing devices of the present disclosure provide adjustable mounting points or holes that can be moved to match mounting points or holes of electronic components/modules of various sizes. Thus, a user has the ability to mount electronic components/modules of different sizes onto the chassis of electronic equipment whether the equipment is in the factory or in the field. Benefits of the present disclosure include chassis inventory reduction, ability to use same existing hard tooling to make the chassis, and ground continuity for power supplies.

It will be appreciated that the invention is not restricted to the particular embodiment that has been described, and that variations may be made therein without departing from the scope of the invention as defined in the appended claims, as interpreted in accordance with principles of prevailing law, including the doctrine of equivalents or any other principle that enlarges the enforceable scope of a claim beyond its literal scope. Unless the context indicates otherwise, a reference in a claim to the number of instances of an element, be it a reference to one instance or more than one instance, requires at least the stated number of instances of the element but is not intended to exclude from the scope of the claim a structure or method having more instances of that element than stated. The word “comprise” or a derivative thereof, when used in a claim, is used in a nonexclusive sense that is not intended to exclude the presence of other elements or steps in a claimed structure or method.

1. A chassis for electronic equipment, comprising:
a base;
at least one elongate connector having opposed first and second longitudinal end portions, the first longitudinal end portion being pivotably connected to the base; and
a coupler attached to, or formed with, the second longitudinal end portion, the coupler adapted to receive a fastener.

2. The chassis of claim 1, wherein the first longitudinal end portion includes a first hole, and further comprising a pivot that is received in the first hole and that is attached to, or formed with, the base.

3. The chassis of claim 2, further comprising a washer disposed between the at least one elongate connector and the base.

4. The chassis of claim 3, wherein the washer is attached to, or formed with, the pivot.

5. The chassis of claim 1, wherein the coupler is a standoff having an aperture to receive a fastener.

6. The chassis of claim 5, wherein the second longitudinal end portion includes a second hole and the standoff is received in the hole.

7. The chassis of claim 1, wherein the coupler includes opposed third and fourth longitudinal end portions, the third longitudinal end portion being attached to, or formed with, the second longitudinal end portion of the coupler, the fourth longitudinal end portion having an aperture to receive a fastener.

8. The chassis of claim 7, wherein the aperture is a threaded aperture.

9. The chassis of claim 1, wherein the base includes at least one stopper attached to, or formed with, the base adjacent to the at least one elongate connector, the at least one stopper limiting pivoting of the at least one elongate connector.

10. The chassis of claim 9, wherein the at least one stopper includes first and second stoppers, the at least one elongate connector being disposed between the first and second stoppers, the first and second stoppers limiting pivoting of the at least one elongate connector to between the first and second stoppers.

11. The chassis of claim 1, wherein the at least one elongate connector includes a first elongate connector and a second elongate connector, the first and second elongate connectors are spaced from each other and positioned on the base such that each of the first and second elongate connectors is adjacent a corresponding corner of an electronic component secured to the coupler of the first and second elongate connectors.

12. The chassis of claim 11, wherein the first and second elongate connectors are pivotable between a first position in which each of the first and second elongate connectors is adjacent a corresponding corner of an electronic component having a first footprint, and a second position in which each of the first and second elongate connectors is adjacent a corresponding corner of an electronic component having a second footprint larger than the first footprint.

13. The chassis of claim 11, wherein the at least one elongate connector further includes third and fourth elongate connectors spaced away from each other and from the first and second elongate connectors, the first, second, third, and fourth elongate connectors being positioned on the base such that each of the first, second, third, and fourth elongate connectors is adjacent a corresponding corner of the electronic component.

14. The chassis of claim 13, wherein the first, second, third, and fourth elongate connectors are pivotable between a first position in which each of the first, second, third, and fourth elongate connectors is adjacent a corresponding corner of an electronic component having a first footprint, and a second position in which each of the first, second, third, and fourth elongate connectors is adjacent a corresponding corner of an electronic component having a second footprint larger than the first footprint.

15. The chassis of claim 1, wherein the base is planar and elongate.

16. The chassis of claim 1, wherein the at least one elongate connector is planar.
